(19) United States
(12) Patent Application Publication
(10) Pub. No.: US 2009/0234609 A1
(43) Pub. Date: Sep. 17, 2009

(54) BATTERY CAPACITY DETECTION DEVICE FOR PORTABLE ELECTRONIC APPARATUS AND DETECTION METHOD THEREOF

(75) Inventor: Chih-Ching TENG, Taipei (TW)

Correspondence Address: EGBERT LAW OFFICES, 412 MAIN STREET, 7TH FLOOR, HOUSTON, TX, 77002, US

(73) Assignee: INVENTEC APPLIANCES Corp., Taipei (TW)

(21) Appl. No.: 12/396,354

(22) Filed: Mar. 2, 2009

(30) Foreign Application Priority Data
Mar. 13, 2008 (TW) 097108913

(51) Int. Cl. G01N 27/416; G01R 35/00

(52) U.S. Cl. 702/85; 324/431

(57) ABSTRACT

A battery capacity detection device for a portable electronic apparatus and the method thereof are disclosed. The portable electronic apparatus has a battery with a capacity. The battery capacity detection method includes the following steps: a plurality of capacity values and a plurality of temperature values are provided, and each of the capacity values corresponds to one of the temperature values; a temperature surrounding the battery is sensed by a sensing unit, and a temperature signal is generated; the temperature signal is then compared with the temperature values for finding a matched temperature value and obtaining the capacity value corresponding to the matched temperature value; and the capacity of the battery is adjusted according to the capacity value corresponding to the matched temperature value.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates to a battery capacity detection method, and more particularly to a battery capacity detection method capable of adjusting the battery capacity according to temperature change.

2. Description of Related Art Including Information Disclosed Under 37 CFR 1.97 and 37 CFR 1.98

FIG. 1 is a flowchart showing the steps included in a conventional battery capacity indicating method for a mobile phone. As shown, a capacity sensor senses the capacity of a battery for a mobile phone and generates a sensing result signal (step 11). The sensing result signal is transmitted to a processing unit of the mobile phone for converting the sensing result signal into an icon or a numeral to indicate the battery capacity (step 12). The converted icon or numeral is shown on a display of the mobile phone for a user's reference (step 13). Since what a user most concerns intuitively is not the sensed capacity value but a ratio of the remaining capacity value to a fully charged capacity expressed in percentage, or the time period over which the mobile phone can still operate with the remaining capacity. Therefore, the processing unit is designed to convert the sensing result signal into an icon or a numeral.

It is noted the above-described conventional battery capacity indicating method for mobile phone does not consider the influence of temperature on battery capacity. As a chemical property of a cell, the same battery under a relatively high temperature will have a capacity larger than that under a relatively low temperature. And, even if a battery is not used or consumed, its capacity will still increase with rising temperature. Therefore, ignoring of the influence of temperature on the battery capacity would result in error in determining the battery capacity by a user, and it is possible the battery is not fully utilized.

It is therefore tried by the inventor to develop a battery capacity detection device for portable electronic apparatus and a detection method thereof in an attempt to accurately show a battery capacity by taking surrounding temperature into consideration.

### BRIEF SUMMARY OF THE INVENTION

An aspect of the present invention is to provide a battery capacity detection device for portable electronic apparatus and a detection method thereof, in which a temperature surrounding a battery is sensed with a sensing element and a capacity of the battery is adjusted based on a temperature vs. capacity parameter table to enable indication of accurate battery capacity.

To achieve the above and other aspects, the battery capacity detection method according to the present invention is applicable to a portable electronic apparatus having a battery with a capacity. In the battery capacity detection method, a plurality of capacity values and a plurality of temperature values are stored, and each of the capacity values corresponds to one of the temperature values. Then, a temperature surrounding the battery is sensed and a temperature signal is generated. The temperature signal is then compared with the stored temperature values to find a matched temperature value. The battery capacity is adjusted according to the capacity value corresponding to the matched temperature value.

The battery capacity detection device for a portable electronic apparatus according to the present invention includes a sensing element, a storage unit, and a processing unit. The sensing element is arranged in the portable electronic apparatus adjacent to a battery of the portable electronic apparatus for sensing a temperature surrounding the battery and generating a temperature signal. The storage unit has a plurality of capacity values and a plurality of temperature values stored therein, and each of the capacity values corresponds to one of the temperature values. The processing unit receives the temperature signal and compares the received temperature signal with the temperature values stored in the storage unit to find a matched temperature value, and adjusts the battery capacity according to the capacity value corresponding to the matched temperature value. Each of the temperature values is preferably a range of temperature, and the capacity value is preferably expressed in percentage.

### BRIEF DESCRIPTION OF THE SEVERAL VIEWS OF THE DRAWINGS

The structure and the technical means adopted by the present invention to achieve the above and other objects can be best understood by referring to the following detailed description of the preferred embodiments and the accompanying drawings.

FIG. 1 is a flowchart showing the steps included in a conventional battery capacity indicating method for a mobile phone.

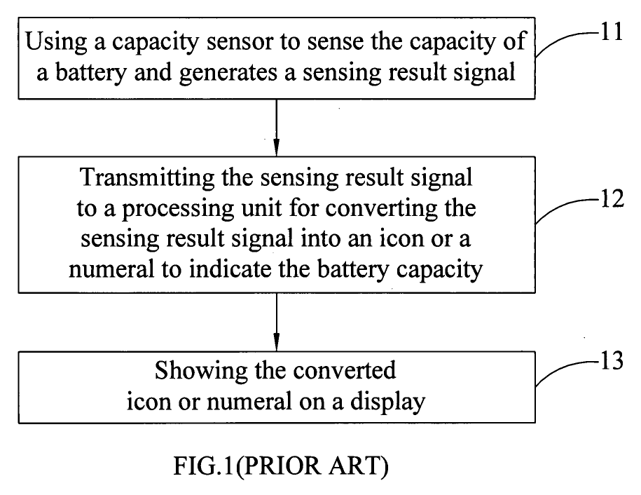

FIG. 2 is a block diagram of a battery capacity detection device for portable electronic apparatus according to an embodiment of the present invention.

FIG. 3 is a flowchart showing the steps included in a battery capacity detection method for portable electronic apparatus according to an embodiment of the present invention.

### DETAILED DESCRIPTION OF THE INVENTION

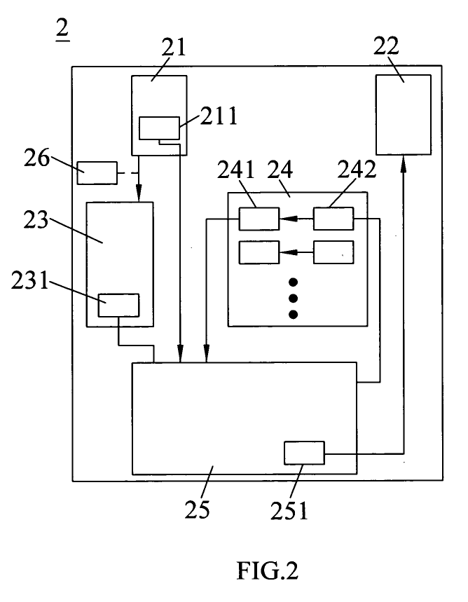

Referring to FIG. 2, there is a block diagram of a battery capacity detection device for portable electronic apparatus according to an embodiment of the present invention. In the illustrated embodiment, the battery capacity detection device is applicable to a portable electronic apparatus 2, which can be a mobile phone, a personal digital assistant (PDA), or a global positioning system (GPS). The portable electronic apparatus 2 has a battery 21 with a capacity 211. The battery capacity detection device includes a display 22, a sensing element 23, a storage unit 24, and a processing unit 25.

The storage unit 24 has a plurality of capacity values 241 and a plurality of temperature values 242 stored therein, and each of the capacity values 241 corresponds to one of the temperature values 242. The sensing element 23 is arranged in the portable electronic apparatus 2 adjacent to the battery 21, so as to sense a temperature 26 surrounding the battery 21 and generate a temperature signal 231 accordingly. The processing unit 25 is electrically connected to the battery 21, the display 22, the sensing element 23, and the storage unit 24. When the sensing element 23 senses the temperature 26 surrounding the battery 21 and generates the temperature signal 231, the processing unit 25 receives the temperature signal 231, compares the temperature signal 231 with the temperature values 242 stored in the storage unit 24, finds one of the temperature values 242 as a matched temperature value that matches the temperature 26 indicated by the temperature signal 231, and reads one of the capacity values 241 that corresponds to the matched temperature value 242. Thereafter, the processing unit 25 adjusts the capacity 211 of the battery 21 according to the capacity value 241 corresponding to the surrounding temperature 26, and generates an adjusted battery capacity 251, which is then shown on the display 22.

Each of the temperature values 242 is preferably a range of temperature, such as −10° C.˜5° C., 5° C.˜15° C., 15° C.˜25° C., 25° C.˜35° C., and above 35° C.; and the capacity values 241 corresponding to the temperature values 242 are expressed in percentage (%), such as 70%, 80%, 90%, 100%, 110%, etc. And, for example, the temperature value −10° C.˜5° C. corresponds to the capacity value of 70%, the temperature value 5° C.˜15° C. corresponds to the capacity value of 80%, the temperature value 15° C.˜25° C. corresponds to the capacity value of 90%, the temperature value 25° C.˜35° C. corresponds to the capacity value of 100%, and the temperature value above 35° C. corresponds to the capacity value of 110%. Preferably, the capacity values 241 and the temperature values 242 are stored in the form of a lookup table.

For instance, when the sensing element 23 senses the temperature 26 surrounding the battery 21 is 30° C., which falls in the range of temperature of 25° C.˜35° C. that corresponds to the capacity value 241 of 100%, the processing unit 25 will multiply the battery capacity by 100% to generate an adjusted capacity and then calculates a ratio of the adjusted capacity to a fully charged capacity of the battery 21. The ratio is then shown by the processing unit 25 on the display 22 as an icon or a numeral. Or, when the sensing element 23 senses the temperature 26 surrounding the battery 21 is 37° C., the corresponding capacity value 241 thereof is 110%. This means it is estimated the battery capacity shall be 10% higher due to the elevated temperature. Therefore, the ratio of the capacity adjusted based on a surrounding temperature of 35° C. to the fully charged capacity would be higher than that obtained at a surrounding temperature of 30° C. In this manner, a user can clearly know the exact present battery capacity. Similarly, when the sensing element 23 senses a surrounding temperature of 17° C., it is estimated the battery capacity would be 10% lower. Therefore, the ratio of the capacity adjusted based on a surrounding temperature of 17° C. to the fully charged capacity would be lower than that obtained at a surrounding temperature of 30° C.

The aforesaid values for the capacity values 241 and temperature values 242 are only for exemplification to help a reader to understand the present invention, and actual values thereof can be supplied by battery manufacturers.

The sensing element 23 is preferably a thermoelectric couple, a thermal resistor, or a temperature sensing element.

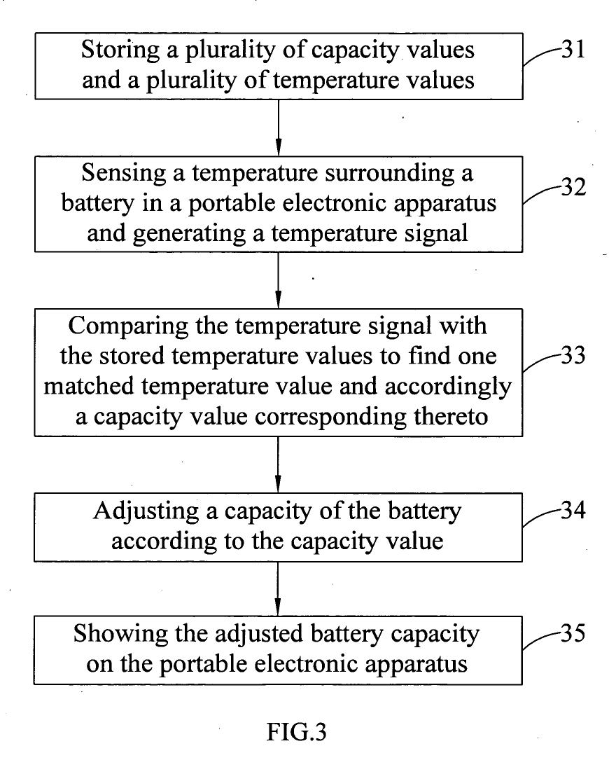

According to the above-described battery capacity detection device for portable electronic apparatus, the present invention further provides a battery capacity detection method applicable to a portable electronic apparatus. Please refer to FIG. 3 that is a flowchart showing the steps included in the battery capacity detection method according to an embodiment of the present invention. A plurality of capacity values and a plurality of temperature values are stored, and each of the capacity values corresponds to one of the temperature values (step 31). A temperature surrounding a battery of the portable electronic apparatus is sensed to generate a temperature signal accordingly (step 32). The temperature signal is compared with the stored temperature values. When one of the stored temperature values matching the temperature signal is found, the capacity value corresponding to the matched temperature value is read (step 33). Then, a capacity of the battery is adjusted according to the read capacity value (step 34). The adjusted battery capacity is shown on the portable electronic apparatus (step 35).

In brief, in view that a battery capacity will increase in a high-temperature environment, the present invention provides further adjustment of the battery capacity according to a sensed temperature surrounding the battery, in order to more accurately reflect the exact capacity of the battery for a user to properly extend the time of using the battery.

1. A battery capacity detection method applicable to a portable electronic apparatus, the portable electronic apparatus being comprised of a battery with a capacity, the method comprising the following steps:
a) storing a plurality of capacity values and a plurality of temperature values, and each of the capacity values corresponding to one of the temperature values;
b) sensing a temperature surrounding the battery and generating a temperature signal accordingly;
c) comparing the temperature signal with the stored temperature values and finding a matched temperature value which is one of the temperature values matching the temperature signal; and
d) adjusting the capacity of the battery according to the capacity value corresponding to the matched temperature value.

2. The battery capacity detection method as claimed in claim 1, wherein the portable electronic apparatus is selected from the group consisting of a mobile phone, a PDA, and a GPS.

3. The battery capacity detection method as claimed in claim 1, wherein the capacity values are expressed in percentage.

4. The battery capacity detection method as claimed in claim 1, wherein each of the temperature values is a range of temperature.

5. The battery capacity detection method as claimed in claim 1, further comprising a step of:
showing the adjusted battery capacity on the portable electronic apparatus.

6. A battery capacity detection device for a portable electronic apparatus, the portable electronic apparatus being comprised of a battery with a capacity, the battery capacity detection device comprising:
a sensing means arranged in the portable electronic apparatus adjacent to the battery for sensing a temperature surrounding the battery and thereby generating a temperature signal accordingly;
a storage means having a plurality of capacity values and a plurality of temperature values stored therein, and each of the capacity values being corresponding to one of the temperature values; and
a processing means for receiving the temperature signal and comparing the temperature signal with the stored temperature values to find one matched temperature value, and adjusting the capacity of the battery according to the capacity value corresponding to the matched temperature value to generated an adjusted battery capacity.

7. The battery capacity detection device as claimed in claim 6, wherein the portable electronic apparatus is selected from the group consisting of a mobile phone, a PDA, and a GPS.

8. The battery capacity detection device as claimed in claim 6, wherein the sensing means is selected from the group consisting of a thermoelectric couple, a thermal resistor, and a temperature sensing element.

9. The battery capacity detection device as claimed in claim 6, wherein the capacity values are expressed in percentage.

10. The battery capacity detection device as claimed in claim 6, wherein each of the temperature values is a range of temperature.

11. The battery capacity detection device as claimed in claim 6, further comprising a display for showing the adjusted battery capacity.
